(19) United States
(12) Patent Application Publication
(10) Pub. No.: US 2012/0164834 A1
(43) Pub. Date: Jun. 28, 2012

(54) Variable-Density Plasma Processing of Semiconductor Substrates

(76) Inventors: Kevin Jennings, Lake Oswego, OR (US); Mohamed Sabri, Beaverton, OR (US); Edward Augustyniak, Tualatin, OR (US); Sunil Kapoor, Vancouver, WA (US); Douglas Keil, West Linn, OR (US)

(21) Appl. No.: 12/976,391

(22) Filed: Dec. 22, 2010

(51) Int. Cl. H01L 21/311; C23F 1/08; C23C 16/50; C23C 16/52; C23C 16/455; C23C 16/458

(52) U.S. Cl. 438/694; 118/697; 118/723 R; 156/345.28; 156/345.51; 257/E21.249

(57) ABSTRACT

Methods and hardware for generating variable-density plasmas are described. For example, in one embodiment, a process station comprises a showerhead including a showerhead electrode and a substrate holder including a mesa configured to support a substrate, wherein the substrate holder is disposed beneath the showerhead. The substrate holder includes an inner electrode disposed in an inner region of the substrate holder and an outer electrode being disposed in an outer region of the substrate holder. The process station further comprises a plasma generator configured to generate a plasma in a plasma region disposed between the showerhead and the substrate holder, and a controller configured to control the plasma generator, the inner electrode, the outer electrode, and the showerhead electrode to effect a greater plasma density in an outer portion of the plasma region than in an inner portion of the plasma region.

### BACKGROUND

Many semiconductor substrate process tools use plasmas during processing. In some plasma-assisted processing tools, the plasma may cause non-uniform processing near the edge of the substrate, leading to substrate thickness non-uniformity. Patterning films with such thickness non-uniformities can be difficult, as it may be difficult for lithography tools to accurately transfer a pattern to non-uniform films.

### SUMMARY

Accordingly, various embodiments are described herein that are related to generating variable-density plasmas having a greater plasma density in an outer portion of the plasma region than in an inner portion of the plasma region. For example, in one embodiment, a semiconductor substrate process station comprises a showerhead including a showerhead electrode, and a substrate holder including a mesa comprising a mesa surface configured to support a substrate, wherein the substrate holder is disposed beneath the showerhead. The substrate holder includes an inner electrode disposed in an inner region of the substrate holder and an outer electrode being disposed in an outer region of the substrate holder. The process station also comprises a plasma generator configured to generate a plasma in a plasma region disposed between the showerhead and the substrate holder, and a controller configured to control the plasma generator, the inner electrode, the outer electrode, and the showerhead electrode to effect a greater plasma density in an outer portion of the plasma region than in an inner portion of the plasma region by coupling the outer electrode with one of the inner electrode and the showerhead electrode.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 schematically shows an example semiconductor substrate process station according to an embodiment of the present disclosure.

FIG. 2 shows a cutaway top perspective view of a substrate holder according to an embodiment of the present disclosure.

FIG. 3 shows a bottom perspective view of the substrate holder shown in FIG. 2,

FIG. 4 shows a cutaway side view of the substrate holder shown in FIGS. 2 and 3.

FIG. 5 shows a close-up cross-sectional view of portion 5 of the substrate holder shown in FIG. 4.

FIG. 6 shows an example electrode set for use with a substrate holder according to an embodiment of the present disclosure.

FIG. 7 shows another example electrode set for use with a substrate holder according to an embodiment of the present disclosure.

FIG. 8 shows another example electrode set for use with a substrate holder according to an embodiment of the present disclosure.

FIG. 9 shows another example electrode set for use with a substrate holder according to an embodiment of the present disclosure.

FIG. 10 shows a flow chart illustrating an embodiment of a method of processing a semiconductor substrate by generating a variable-density plasma in a semiconductor substrate process station.

FIG. 11 schematically shows another example process station according to an embodiment of the present disclosure.

FIG. 12 shows a graph illustrating a relationship between an adjustment of a capacitive control circuit and an amount of power distributed to an inner and an outer electrode according to an embodiment of the present disclosure.

FIG. 13 shows a graph illustrating relationships between electrode power supply, process station pressure, and current density of a variable-density plasma according to an embodiment of the present disclosure.

FIG. 14 shows another graph illustrating relationships between electrode power supply, process station pressure, and current density of a variable-density plasma according to an embodiment of the present disclosure.

FIG. 15 schematically shows another example process station according to an embodiment of the present disclosure.

FIG. 16 shows a graph and a table illustrating a relationship between current density and power distribution according to an embodiment of the present disclosure.

FIG. 17 schematically shows another example process station according to an embodiment of the present disclosure.

FIG. 18 schematically shows another example process station according to an embodiment of the present disclosure.

FIG. 19 shows a graph illustrating a radial current density profile for a plurality of process station electrode configurations according to an embodiment of the present disclosure.

FIG. 20 schematically shows another example process station according to an embodiment of the present disclosure.

FIG. 21 schematically shows an example multi-station process tool according to an embodiment of the present disclosure.

### DETAILED DESCRIPTION

Plasmas for plasma-assisted semiconductor substrate process stations (e.g., plasma etch tools and/or plasma-enhanced chemical vapor deposition tools) may be generated by applying a radio frequency (RF) field to a low-pressure gas using two capacitively coupled plates. Ionization of the gas between the plates by the RF field, ignites a plasma, creating free electrons in the plasma discharge region. These electrons are accelerated, by the RF field and may collide with gas-phase reactant molecules. Collision of these electrons with reactant molecules may form radical species that participate in substrate processing. In some examples, the plasma region may be formed directly above the substrate surface. In one non-limiting example, reactant radicals generated by the plasma may deposit a film layer on the substrate. In another non-limiting example, etchant radicals generated by the plasma may etch the substrate surface.

The plasma discharge region is surrounded by a sheath that forms at the boundaries of the plasma. In some plasma-assisted processing tools (including but not limited to the deposition and etch tools described above), the position of the sheath and the magnitude of the plasma density may cause non-uniform processing near the edge of the substrate, leading to a within-substrate thickness non-uniformity. For example, depending on the process conditions, the substrate may have a convex or a concave non-uniformity.

Patterning films with thickness non-uniformity can be difficult. For example, it may be difficult for downstream lithography tools to accurately transfer a pattern to non-uniform films. Past approaches to avoiding process non-uniformity have used process-specific hardware that may be incompatible with a different process. For example, some past approaches include providing a passive ceramic material at the substrate edge to suppress a portion of the plasma, using a plasma gas distribution showerhead having a non-uniform distribution of holes, and using dish-shaped substrate support surfaces to adjust RF coupling across the substrate. Thus, it will be appreciated that changing the tool between processes, such as between etching and deposition, between different process chemistries, etc. may involve replacement of the showerhead and/or replacement of the substrate support. These replacements may lead to higher consumable parts costs in addition to the downtime expenses associated with changing processes.

Thus, various embodiments are disclosed herein that relate to forming, adjusting, and controlling variable-density plasmas using multiple electrodes in a semiconductor substrate process station to adjust plasma density across the substrate surface. For example, in one embodiment, the variable-density plasma may be adjusted and controlled to effect a greater plasma density in an outer portion of the plasma region near a substrate edge than in an inner portion of the plasma region farther from the substrate edge. Accordingly, it will be appreciated that some of the embodiments described herein may be employed to avoid or reduce within-substrate non-uniformity during a process at the semiconductor substrate process station, and that some of the embodiments described herein may be employed to mitigate or compensate for incoming within-substrate non-uniformity during a process at the process station.

Further, various embodiments are disclosed herein that are related to controlling and adjusting a variable-density plasma to direct floating particles away from the substrate surface as a plasma is being ignited and/or as a plasma is being quenched. As explained above, during processing, a plasma may be formed above the substrate surface, which may provide a greater plasma density and enhance a substrate processing rate. However, small particles may form within the plasma from various deposition and etching reactions. These small particles “float” electrically, so that electron and ion currents are balanced on the particle surface. Because an electron typically has a higher mobility than an ion, the particle may become negatively charged. Consequently, these particles may be trapped at plasma sheath boundaries, where molecular drag forces from neutral and ionized species directed, toward the deposition surface balance electrostatic forces directed toward the plasma discharge region.

Quenching the plasma extinguishes the electrostatic forces, which may cause the particles to land on the substrate surface. Particles that decorate the substrate surface may appear as interface roughness defects or interface morphology defects and may ultimately diminish device performance and reliability. Some approaches to mitigating defects created by plasma-generated particles include alternating pumping and purging of the reactor environment. However, these approaches may be time consuming and may reduce tool throughput. Thus, directing floating particles away from the substrate surface may help to avoid such problems.

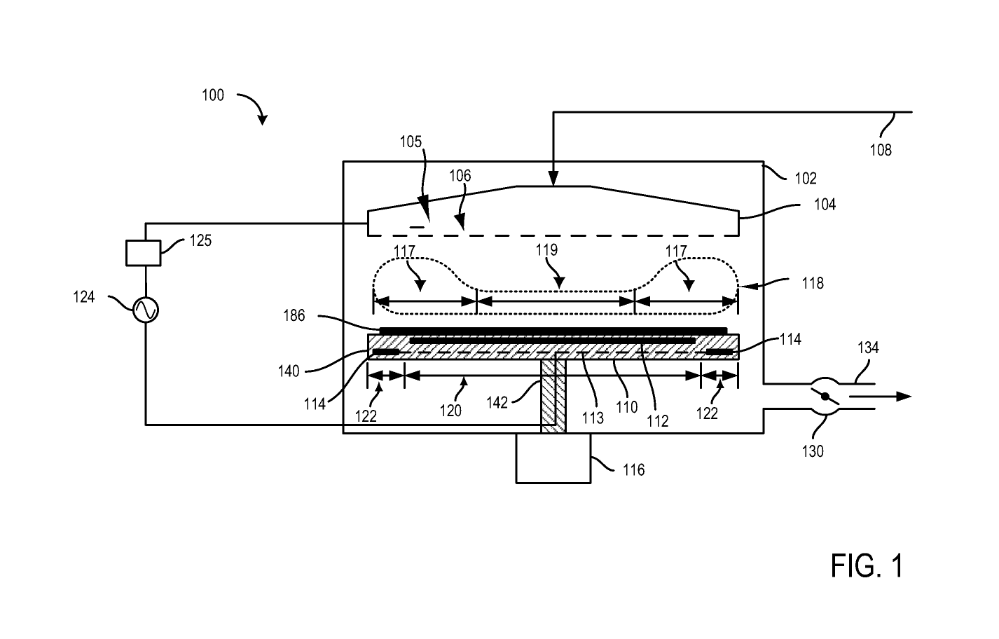

FIG. 1 schematically shows an embodiment of a semiconductor substrate process station 100, including a vacuum chamber 102 for maintaining a low pressure environment around substrate 186 during processing. Vacuum chamber 102 is fluidly connected with an exhaust line 134 and a pressure control valve 130.

Semiconductor substrate process station 100 also includes a gas-distribution showerhead 104 for distributing process gases to a variable-density plasma region 118 and substrate 186 during processing, and a substrate holder 110 for supporting substrate 186 during processing.

As shown in FIG. 1, showerhead 104 includes a plurality of holes 106 through which various process gases received via one or more process gas feed lines 108 may be distributed within vacuum chamber 102. While showerhead 104 is shown as a single-plenum showerhead in FIG. 1, in some embodiments, a dual- or a multi-plenum configuration may be provided to segregate potentially incompatible process gases from interacting within showerhead 104. Further, while holes 106 are shown to have a uniform radial distribution in FIG, 1, it will be appreciated that any suitable radial and/or azimuthal distribution of holes 106 may be employed in some embodiments without departing from the scope of the present disclosure.

In the embodiment depicted in FIG, 1, a portion of showerhead 104 forming a

showerhead electrode 105 is shown in electrical connection with plasma generator 124. Plasma generator 124 is controlled by a plasma generator controller 125. Plasma generator controller 125 may, in some embodiments, include one or more of various matching circuits (which, in some embodiments, may include a tap-phase circuit), distribution networks, and capacitive controllers (as described below) so that, during a plasma condition, power supplied by plasma generator 124 to showerhead electrode 105 may couple with an outer electrode provided in substrate holder 110 (discussed below) to form variable-density plasma region 118, comprising an inner portion 119 and an outer portion 117, above the surface of substrate 186.

While the example showerhead electrode 105 shown in FIG. 1 is electrically connected with plasma generator 124, it will be appreciated that, in some embodiments (discussed below), showerhead electrode 105 may be electrically grounded. Further, though the example showerhead electrode 105 shown in FIG. 1 integrally forms a portion of showerhead 104, it will be appreciated that, in some embodiments, showerhead electrode 105 may be separate from showerhead 104.

In the depicted embodiment, substrate holder 110 is disposed beneath showerhead 104, so that substrate 186 is directly exposed to variable-density plasma region 118 during processing. Substrate holder 110 is configured to retain substrate 186 on a mesa 140, mesa 140 comprising a dielectric material and being supported by column 142 in the example shown in FIG. 1. In some embodiments, substrate holder 110 may be thermally coupled with a heater 116 to provide heat to substrate 186 during processing. Substrate holder 110 may also be mechanically or fluidly coupled to a rotation unit and/or an elevator unit (not shown) to provide rotational and/or height adjustment, respectively, for substrate holder 110 with respect to showerhead 104.

As shown in FIG. 1, mesa 140 (depicted in cross-section in FIG. 1) includes at least one outer electrode 114 disposed in an outer region 122 of mesa 140 and at least one inner electrode 112 disposed in an inner region 120 of mesa 140. As described in more detail below, plasma controller 125 may control plasma generator 124, showerhead electrode 105, inner electrode 112 and outer electrode 114 to effect a greater plasma density in outer portion 117 of variable-density plasma 118 than in inner portion 119. For example, in some embodiments, plasma controller 125 may control plasma generator 124 to power showerhead electrode 105 and/or inner electrode 112 and/or outer electrode 114 to generate variable density plasma 118. Though outer region 122 and inner region 120 of mesa 140 are not depicted in alignment with outer portion 117 and inner portion 119 of variable-density plasma 118, it will be appreciated that, in some embodiments, inner region 120 and inner portion 119 may substantially align and outer region 122 and outer portion 117 may substantially align.

In the embodiment depicted in FIG. 1, left- and right-hand portions of outer electrode 114 are electrically connected by a conductive arm 113. As shown in FIG. 1, outer electrode 114 is a single electrode that is electrically connected with plasma generator 124. However, in some embodiments including a plurality of outer electrodes 114, one or more of a first set of outer electrodes 114 may be electrically isolated from one or more of a second set of outer electrodes 114, so that the first and second sets may be controlled as electrically independent outer electrode zones, one or more of which may receive power from plasma generator 124.

Inner electrode 112 is disposed in mesa 140 and is separated from outer electrode 114 by a layer of dielectric material from which mesa 140 is formed, or in any other suitable manner. In the example shown in FIG. 1, inner electrode 112 is electrically grounded (not shown). However, in some embodiments discussed below, inner electrode 112 may be electrically connected to plasma generator 124. As shown in FIG. 1, inner electrode 112 is a single electrode disposed beneath substrate 186. However, in other embodiments, mesa 140 may comprise a plurality of inner electrodes 112, a first set of inner electrodes being electrically isolated from a second set of inner electrodes so that they may be controlled as electrically independent inner electrode zones.

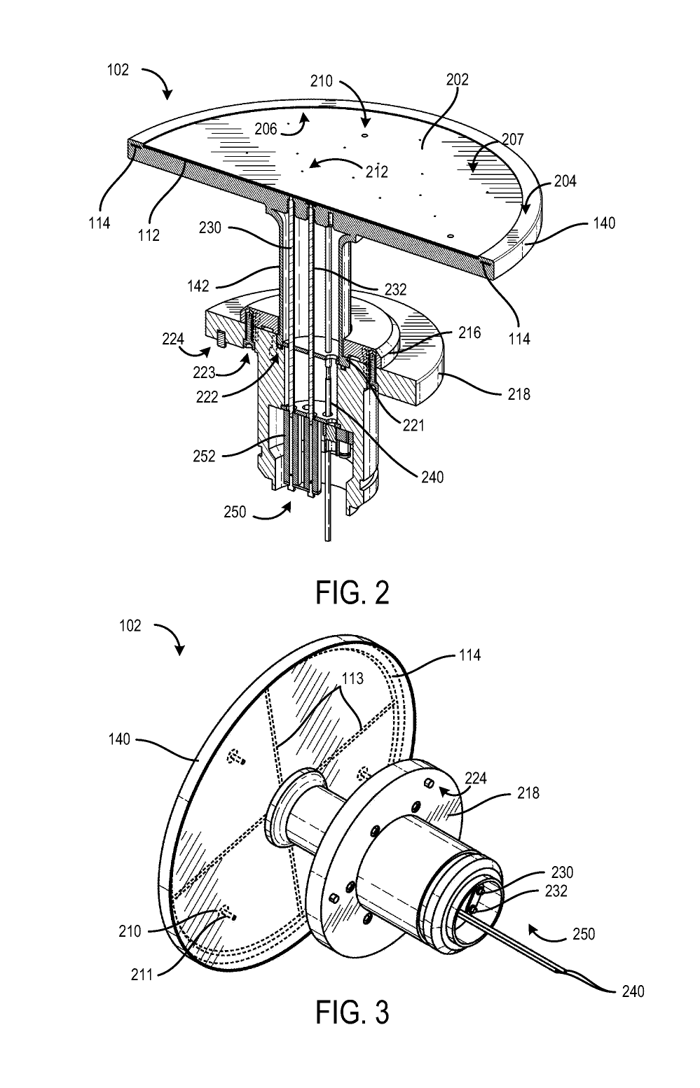

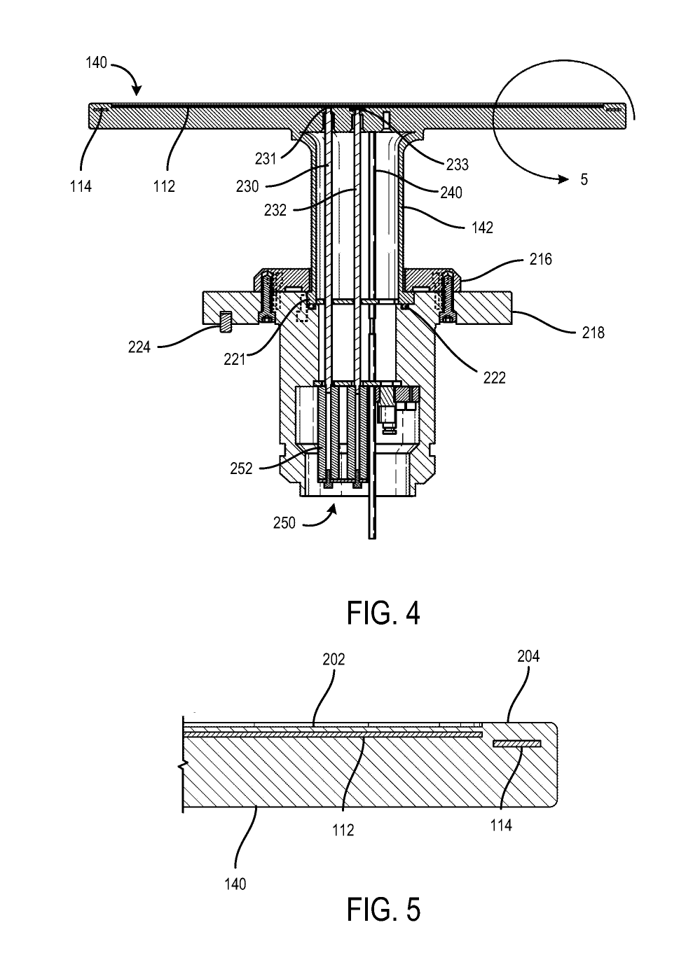

FIGS. 2 and 3 schematically show a cutaway top perspective view of substrate holder 110 and a bottom perspective of substrate holder 110, respectively. FIG. 4 shows a cutaway side view of substrate holder 110 taken along the cutaway plane shown in FIG. 2.

As shown in FIG. 2, mesa 140 includes a top surface 202 configured to support substrate 186. Mesa 140 includes a plurality of raised contact points 212 protruding from top surface 202 that contact a backside of substrate 186 when the substrate is resting on substrate holder 110, and a plurality of lift pin holes 210 from which lift pins 211 (shown in FIG. 3) may emerge to raise and lower substrate 186 so that an end effector or paddle may pass between top surface 202 and the backside of substrate 186 during a substrate transfer operation. Mesa 140 may have any suitable size. In one example used for supporting 300 mm silicon wafers, mesa 140 has a diameter of approximately 12.75 inches.

Optionally, in some embodiments, such as in the example shown in FIG. 2, mesa 140 may include a raised edge 204 around all or a portion of mesa 140, such that an interior lip 206 of raised edge 204 and top surface 202 define a wafer pocket 207. In one example including wafer pocket 207, a tolerance between an edge of substrate 186 and lip 206 may be approximately 1.5 mm, a height of raised edge 204 may be approximately 1.27 mm as measured from a top surface of raised edge 204 to top surface 202, and a diameter of wafer pocket 207 may be approximately 11.9 inches.

Additionally or alternatively, in some embodiments including wafer pocket 207, one or more gaps (not shown) may be included in raised edge 204. In one example, four symmetrically spaced 2-in. gaps may be disposed, around raised edge 204.

Top surface 202 is formed from a suitable dielectric material to prevent direct electrical connection between substrate 186 and the electrodes included in mesa 140. In some examples, mesa 140 and top surface 202 may be formed from a ceramic material like aluminum nitride, which may be compacted and sintered during manufacturing. Alternatively, it will be appreciated that, in some embodiments, top surface 202 and portions of mesa 140 may be formed from different dielectric materials (e.g., materials having a similar coefficient of thermal expansion) that are suitably assembled or bonded together.

Mesa 140 is supported by column 142. In the example shown in FIGS. 2 and 3, mesa 140 and column 142 are a unitary pedestal piece, though it will be appreciated that, in some embodiments, mesa 140 and column 142 may be suitably joined from separate pieces suitably into a pedestal assembly. Column 142 includes a flange 221 configured to mate with a feedthrough spool 218 and a collar 216. A gasket 222 seals flange 221 against a complementary mating surface of feedthrough spool 218 under the urging of collar 216, so that, once sealed, an interior of column 142 may be maintained at a comparatively higher pressure (e.g., an ambient pressure) than the vacuum environment of vacuum chamber 102. A plurality of bolts 223 are provided to secure feedthrough spool 218 to collar 216, though it will be appreciated that any suitable connector for sealing flange 221 against the complementary mating surface of feedthrough spool 218 may be employed without departing from the scope of the present disclosure.

Feedthrough spool 218 is configured to provide electrical connections between

outside power sources and inner electrode bus 230, outer electrode bus 232, and heater bus 240 included within column 142. FIGS. 2 and 4 show inner electrode 112 electrically connected to inner electrode bus 230 at inner electrode connection point 231. FIG, 3 shows a plurality of conductive arms 113 configured to electrically connect outer electrode 114 with outer electrode bus 232 at outer electrode connection point 233, though it will be appreciated that in some embodiments a single conductive arm 113 may connect outer electrode connection point 233 with outer electrode 114. Outer electrode bus 232 and inner electrode bus 230 terminate at electrode bus connection 250, which may include a suitable dielectric material 252 to electrically isolate the buses from feedthrough spool 218. Similarly, heater bus 240 may be electrically isolated from feedthrough spool 218 by a suitable dielectric material (not shown).

As shown in FIGS. 2 and 3, feedthrough spool 218 includes one or more locating pins 224 configured to align feedthrough spool 218 to a complementary portion of vacuum chamber 102. While not shown in FIGS. 2 and 3, it will be appreciated that in some embodiments, feedthrough spool 218 may be configured to seal against vacuum chamber 102 when installed therein.

FIG. 5 schematically shows a close-up cross-sectional view of the indicated portion “5” of FIG. 4. As shown in FIG. 5, that inner electrode 112 is disposed in a plane slightly below that of top surface 202, so that a layer of dielectric material separates both the inner electrode from the top surface. In one example, inner electrode 112 may be located approximately 0.05 inches below top surface 202.

FIG. 5 shows outer electrode 114 being disposed in an outer region of mesa 140 and in a plane slightly below a plane of inner electrode 112, so that a layer of dielectric material separates the inner electrode from the outer electrode. In one example, outer electrode 114 may be located approximately 0.10 inches below top surface 202. Further, as shown in FIGS. 4 and 5, an inner diameter of outer electrode 114 is greater than a maximum diameter of inner electrode 112, so that there is a horizontal gap between inner electrode 112 and outer electrode 114 as well as the vertical gap described above. In one example, an inner diameter of outer electrode 114 may exceed a maximum diameter of inner electrode 112 by approximately 5 mm. The horizontal and vertical gaps described above may separate inner electrode 112 from outer electrode 114 to avoid electrical arcing between the electrodes while permitting a predetermined amount of coupling between the electrodes. These gaps may be configured, based on predetermined power ranges for each of the electrodes and a dielectric breakdown value for the dielectric material, among other considerations. The vertical gap may also provide a suitable separation between inner electrode 112 and conductive arms 113, though it will be appreciated that portions of conductive arms 113 may be located at a greater depth from inner electrode 112 relative to outer electrode 114.

Inner electrode 112, outer electrode 114, and conductive arms 113 may be fabricated from any suitable conductive material or materials. One non-limiting example of a conductive material is aluminum. Further, inner electrode 112, outer electrode 114, and conductive arms 113 may be fabricated in any suitable way. In one example, they may be fabricated from metal mesh inserted into mesa 140 during fabrication. In another example, they may be fabricated by lithographically patterning a metal film during fabrication of mesa 140.

As shown in FIGS. 2-5, the depicted embodiment of inner electrode 112 comprises a single, substantially disc-shaped electrode and outer electrode 114 is a single, substantially ring-shaped electrode. More specifically, the examples shown in FIGS. 2-5 show a geometric center of the inner electrode being concentric with a geometric center of the mesa surface and with a geometric center of the outer electrode. However, it will be appreciated that any suitable complementarily-shaped set of electrodes may be employed in any suitable arrangement without departing from the scope of the present disclosure. Thus, it will be appreciated that, in some embodiments, the inner and outer electrodes may be configured to provide radial and azimuthal control of plasma density within variable-density plasma region 118.

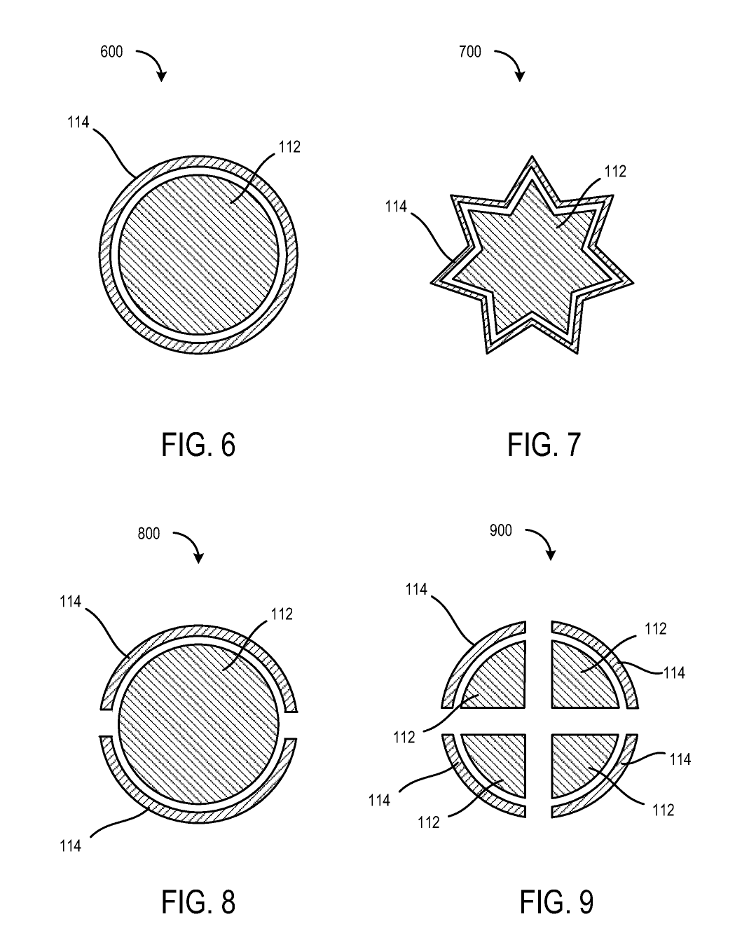

For example, FIGS. 6-9 schematically show various complementarily-shaped electrode sets 600, 700, 800, and 900, respectively, of inner electrodes 112 and outer electrodes 114. Electrode set 600, shown in FIG. 6, depicts a configuration of inner electrode 112 and outer electrode 114 like that shown in FIGS. 2-5, which provides radial control of the variable-density plasma region. Control of a radial plasma density may provide a way to adjust plasma processing parameters in a radial direction. For example, radial control of the plasma density may provide control of concave and toroidal shaped plasmas, which may provide an approach to generate concave- and toroidal-shaped plasmas. Thus, in one example, a generally convex within wafer substrate thickness non-uniformity of a substrate coming from an upstream tool may be partially or completely offset by generating a concave plasma during processing at an embodiment of semiconductor substrate process station 100. In another example, a substrate in process at an embodiment of semiconductor substrate process station 100 may be processed to preemptively offset a known non-uniformity pattern characteristic of a downstream tool.

Electrode set 700 of FIG. 7 also may provide radial control of plasma density for a star-shaped complementary set of electrodes. Electrode set 800 of FIG. 8 includes a plurality of outer electrodes 114, and electrode set 900 of FIG. 9 includes a plurality of both inner electrodes 112 and outer electrodes 1.14, either of which may provide both radial and azimuthal control of variable-density plasma region 118. By providing azimuthal control of plasma density as well radial control, wedge-shaped plasmas may be generated, potentially providing an approach to generate a wedge-shaped plasma during processing, which may be used to offset thickness non-uniformities associated with upstream and/or downstream tools.

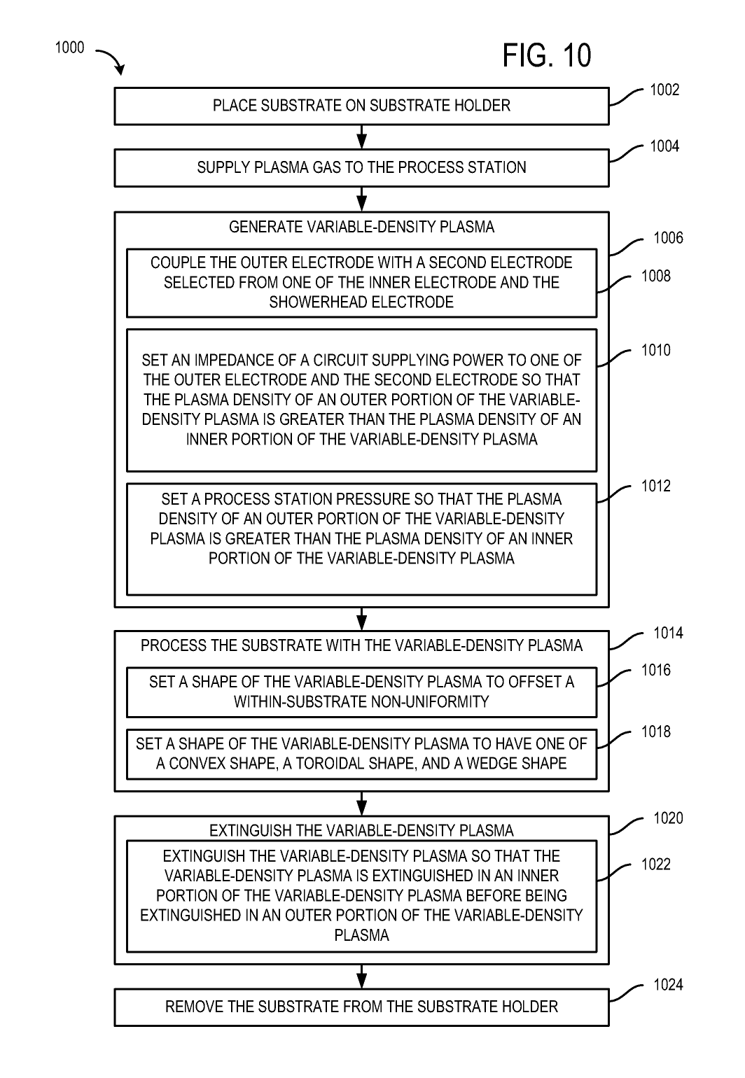

It will be understood that the hardware described above may be used to generate a variable-density plasma across a substrate. FIG. 10 shows a flow chart illustrating an embodiment of a method 1000 of processing a semiconductor substrate by generating a variable-density plasma in a semiconductor substrate process station. However, it will be appreciated that, in some embodiments, portions of method 1000 may be arranged in a different order, may be omitted, or may be supplemented without departing from the scope of the present disclosure. At 1002, method 1000 comprises placing a substrate on the substrate holder. At 1004, method 1000 comprises supplying a plasma gas to the semiconductor substrate process station.

At 1006, method 1000 comprises generating the variable-density plasma by, at 1008, coupling the outer electrode with one of the inner electrode and the showerhead electrode. In some embodiments, coupling of the outer electrode with the second electrode may be realized by distributing power from one or more plasma generators to two electrodes selected from the outer electrode, the inner electrode, and the showerhead electrode while the third electrode is electrically grounded.

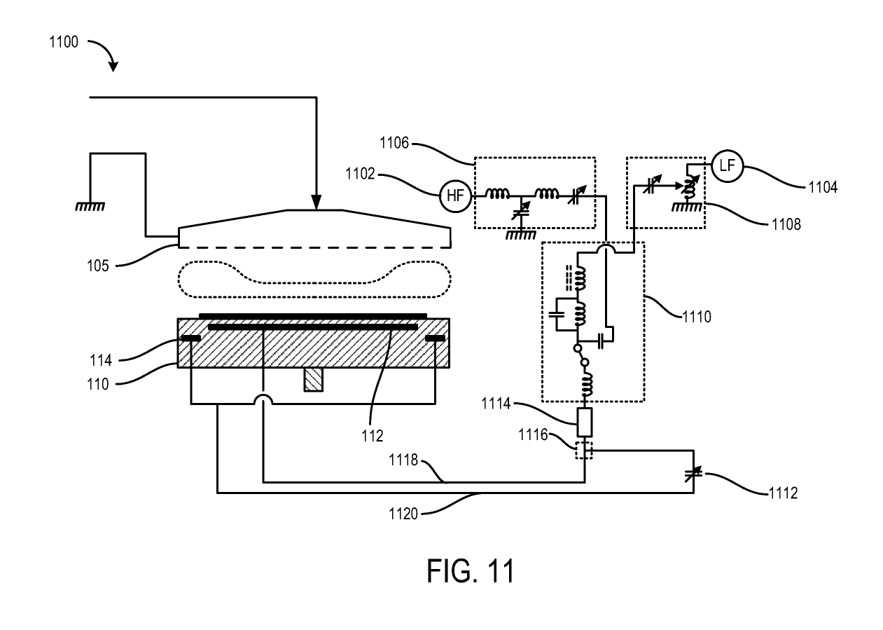

FIG. 11 schematically shows an embodiment of a process station 1100 including a substrate holder 110 having outer electrode 114 coupled with an inner electrode 112. The example process station 1100 shown in FIG. 11 includes a high-frequency plasma generator 1102, a low-frequency plasma generator 1104 and a showerhead electrode 105. In some embodiments, high-frequency plasma generator 1102 may produce frequencies between 2 MHz and 60 MHz at power levels between 30 watts and 5000 watts. Further, in some embodiments, low-frequency plasma generator 1104 may produce frequencies between 1 KHz and 2 MHz and power levels between 30 watts and 5000 watts. While FIG. 11 depicts both high- and low-frequency plasma generators, it will be appreciated that, in some embodiments, only one type of plasma generator may be employed (e.g., only high-frequency plasma generator 1102 or low-frequency plasma generator 1104) without departing from the scope of the present disclosure.

In the example depicted in FIG. 11, high-frequency plasma generator 1102 is electrically connected, to a matching circuit 1106 configured to match a impedance of high-frequency plasma generator 1102 and a distribution circuit 1110 configured to distribute power to power branches supplying the inner and outer electrodes. In the example shown in FIG. 11, distribution circuit 1110 includes an LC circuit. Low-frequency plasma generator 1104 is electrically connected to a low-frequency matching circuit 1108, configured to provide matching impedance (in some embodiments, approximately 50 ohms), and is electrically connected to distribution circuit 1110. An optional cable 1114 (e.g., a co-axial cable in some embodiments) is included to connect the distribution and/or matching circuit to a respective electrode. At branch point 1116, power from distribution circuit 1110 is divided between an inner electrode power branch 1118 feeding power to inner electrode 112 and an outer electrode power branch 1120 feeding power to outer electrode 114.

Continuing with FIG. 10, method 1000 comprises, at 1010, setting an impedance of a circuit supplying power to one of the outer electrode and the second electrode so that the plasma density of an outer portion of the variable-density plasma is greater than the plasma density of an inner portion of the variable-density plasma. In the embodiment shown in FIG. 11, the plasma generators are electrically connected to inner electrode 112 and outer electrode 114, and showerhead electrode is electrically grounded, so that, when power is applied to inner electrode 112 and outer electrode 114, an electric field of each will couple with the other. Control of a degree of coupling is provided by a capacitive controller 1112 electrically connected with a branch providing power to outer electrode 114. As shown in FIG. 11, capacitive controller 1112 provides capacitive control and adjustment of a power supplied to outer electrode 114. In one non-limiting example, capacitive controller 1112 may provide adjustment of capacitance in a range of approximately 40 pF to approximately 600 pF, though it will be appreciated that other ranges may be appropriate depending on electrode impedance and power supply capacity. Further, in the example shown in FIG. 11, varying the impedance of outer electrode power branch 1120 at capacitive controller 1112 may vary an amount of high-frequency plasma power in outer electrode power branch 1120 more than an amount of a low-frequency plasma power. However, it will be appreciated that, in some embodiments, capacitive controller 1112 may be configured to vary high-frequency and/or low-frequency plasma power supplied to outer electrode power branch 1120 in any suitable way.

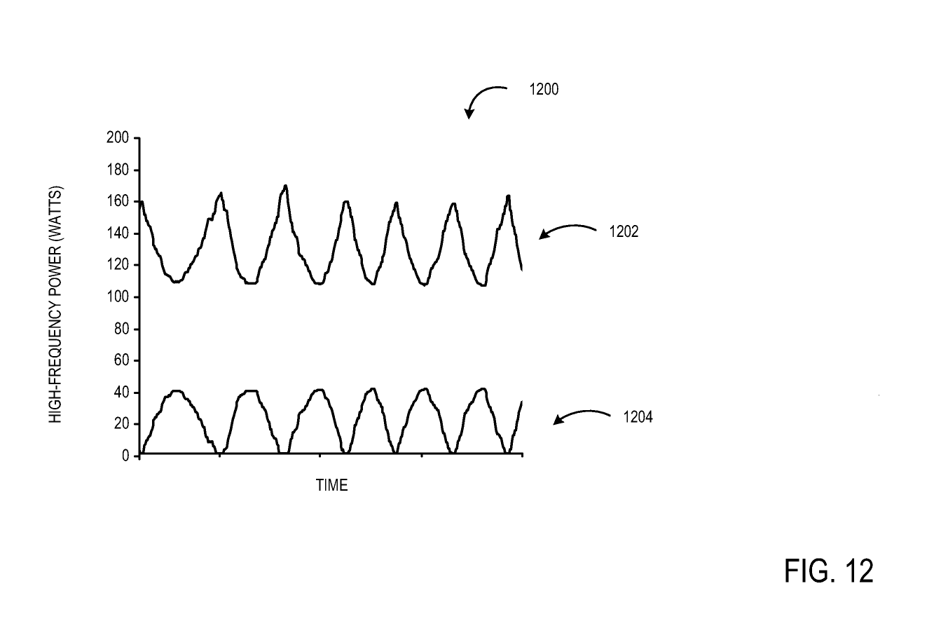

FIG. 12 shows a graph 1200 illustrating a relationship between an adjustment of a capacitive control circuit supplying power to one of the outer electrode and the second electrode and an amount of power distributed to the outer electrode (curve 1204) and the inner electrode (curve 1202). In the example shown in FIG. 12, the capacitive controller was arbitrarily adjusted back and forth to demonstrate power division between the electrodes. Because a single plasma generator was used in this example, FIG. 12 shows that increasing power supplied to the outer electrode results in a corresponding decrease in power supplied to the inner electrode. However, it will be appreciated that, in some embodiments, two or more plasma generators may be connected to different electrodes so that an adjustment to power supplied to one electrode may not affect power supplied to another electrode (discussed in more detail below).

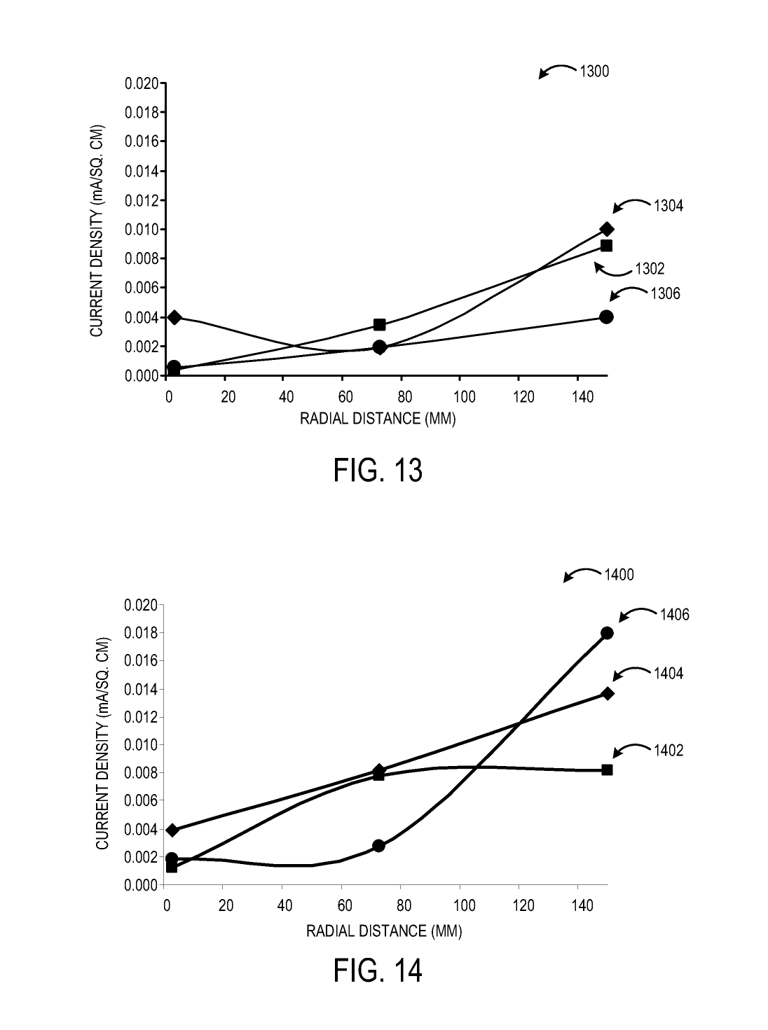

Local plasma density may be measured with a plasma probe that samples an amount of ion current drawn from the plasma at a given voltage. In some plasmas, a higher ion current may correlate with a higher plasma density while a lower ion current may correlate with a lower plasma density. FIGS. 13 and 14 show graphs 1300 and 1400, respectively, which illustrate an example relationship between probe ion current density as a function of substrate radius. In the embodiments shown in FIGS. 13 and 14, 0 mm is defined as the center of the substrate and 150 mm is the edge of a 300-mm substrate. As shown in FIGS. 13 and 14, probe ion current density varies as power supplied to the outer electrode is increased from approximately 0 W, as shown in FIG. 13, to approximately 35-41 W, as shown in FIG. 14, and as power supplied to the inner electrode is decreased from approximately 160-170 W to approximately 111-115 W. As explained above, it will be appreciated that probe ion current density may be used to approximate plasma density; thus, FIGS. 13 and 14 illustrate that increasing power to the outer electrode increases plasma density in an outer portion of the variable-density plasma.

Continuing with FIG. 10, in some embodiments, method 1000 may comprise, at 1012, setting a process station pressure so that the plasma density of an outer portion of the variable-density plasma is greater than the plasma density of an inner portion of the variable-density plasma. In some embodiments, plasma density distribution may vary as a function of process station pressure. FIGS. 13 and 14 also illustrate the effect of increasing pressure within the process station—from approximately 1 torr (curves 1302 and 1402) to approximately 2 torr (curves 1304 and 1404) to approximately 4 torr (curves 1306 and 1406)—on radial current distribution. Thus, it will be appreciated that, in some embodiments, adjusting the process station pressure and varying the power supplied to one of the outer electrode and the second electrode may further adjust the density of the variable-density plasma in an outer portion of the variable-density plasma. It will be appreciated that, in some embodiments, other process station parameters may be adjusted or controlled to adjust or maintain a plasma density distribution within a variable-density plasma. Non-limiting examples of such process station parameters include process gas composition (i.e., the composition of a gas mixture fed to the process station, including various diluent, plasma, and reactive gases), total process gas flow rate, process station temperature (e.g., the temperatures of various surfaces in the process station near the plasma discharge region).

Continuing with FIG. 10, method 1000 comprises, at 1014, processing the substrate with the variable-density plasma. For example, in some embodiments, processing the substrate may comprise depositing a film on a substrate using a plasma-enhanced chemical vapor deposition (PECVD) technique. In another example, in some embodiments, processing the substrate may comprise etching a film on a substrate using a plasma-activated dry etch technique.

As explained above, providing a variable-density plasma may provide approaches to mitigate process-specific non-uniformity patterns, including those native to the process station and those native to upstream and downstream process tools. Consequently, in some embodiments, a within-substrate non-uniformity profile of an incoming substrate may be comparatively flatter after processing. This may provide comparatively flatter substrate surfaces for subsequent lithography steps.

Thus, in some embodiments, method 1000 may comprise, at 1016, setting the shape of the variable-density plasma to offset within-substrate non-uniformity. Additionally or alternatively, in some embodiments, method 1000 may comprise, at 1018, setting a shape of the variable-density plasma to have one of a convex shape, a toroidal shape, and a wedge shape. For example, if an upstream process tool generates a convex thickness profile on the substrate, subsequent PECVD processing with a variable-density plasma may deposit additional film near the substrate edges to offset the convex profile. This may result in a comparatively more even coverage and development of photoresist spun onto the substrate at a lithography track tool and more uniform exposure at a stepper operation.

At 1020, method 1000 comprises extinguishing the variable-density plasma. As explained above, in some plasma processes, small particles “float” electrically in the plasma. Quenching the plasma extinguishes the electrostatic forces on the surfaces of such particles, which may cause the particles to land on the substrate surface. Thus, in some embodiments, method 1000 comprises, at 1022, extinguishing the variable-density plasma so that the variable-density plasma is extinguished in an inner portion of the variable-density plasma before being extinguished, in an outer portion of the variable-density plasma. This may cause the small particles to be carried away as the plasma sheath retreats from the inner portion of the plasma, potentially avoiding defect-causing decoration of the substrate surface during plasma extinction. Once the plasma is extinguished, method 1000 may comprise, at 1024, removing the substrate from the substrate holder.

It will be appreciated that method 1000 may be used with any suitable power supply and electrode configuration, including the configuration described above and including various other embodiments described in more detail below. For example, in some embodiments, a capacitance and/or an impedance of a power branch electrically connected with the outer electrode may be adjusted to balance an impedance of the outer electrode with an impedance of the second electrode (i.e., the inner electrode or the showerhead electrode). This may provide a current balance and/or a power balance between the respective power branches, which may provide a more stable plasma relative to the example shown in FIG. 11.

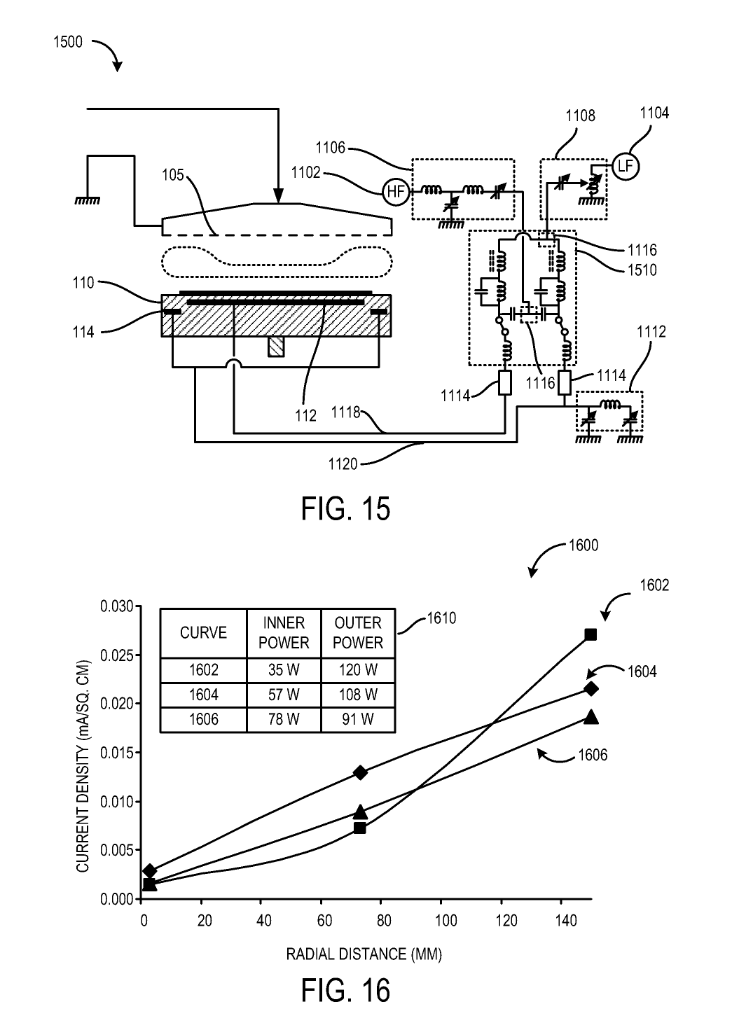

FIG. 15 schematically shows an example process station 1500 having an electrode configuration like that of process station 1100 of FIG. 11. However, unlike the example shown in FIG. 11, process station 1500 includes a dual-branch distribution circuit 1510, each branch of which is configured to receive power from branch points 1116 and distribute power to an inner electrode power branch 1118 and an outer electrode power branch 1120. Further, in the example shown in FIG. 15, capacitive controller 1112 is configured to vary both of an amount of high-frequency plasma power and an amount of a low-frequency plasma power supplied to outer electrode power branch 1120. However, it will be appreciated that, in some embodiments, capacitive controller 1112 may be configured to vary high-frequency and/or low-frequency plasma power supplied to outer electrode power branch 1120 in any suitable way.

FIG. 16 shows graph 1600 illustrating plasma probe current density distributions in a radial direction for three different power distribution schemes (see curves 1602, 1604, and 1606, shown in table 1610 of FIG. 16) using an embodiment of a process station configuration similar to process station 1500 of FIG. 15 at a pressure of approximately 2 torr. As shown in FIG. 16, supplying more power to the outer electrode provides a higher current density at the outer edge of the radial profile.

In some embodiments, variable-density plasmas having a greater plasma density at an outer portion of the variable-density plasma than at an inner portion of the variable-density plasma may be generated using configurations where the showerhead electrode is powered and one of the inner electrode and the outer electrode is electrically grounded so long as the outer electrode is coupled with a second electrode selected from one of the inner electrode and the showerhead electrode.

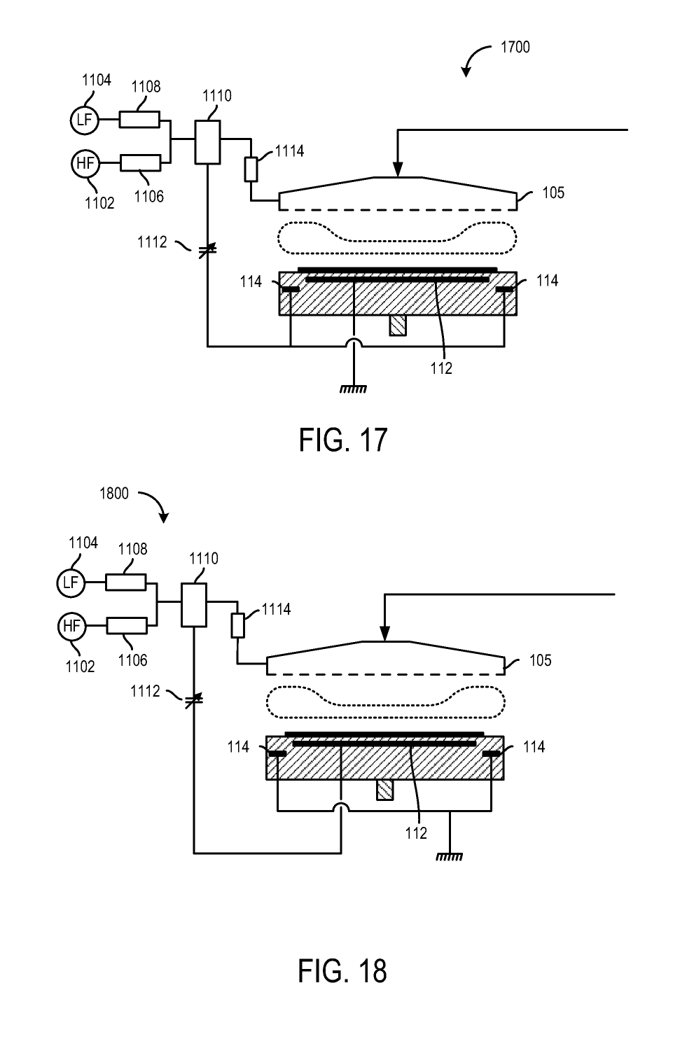

As one example, FIG. 17 schematically shows a process station 1700. In the example shown in FIG. 17, showerhead electrode 105 and outer electrode 114 are electrically connected with high frequency plasma generator 1102 and low frequency plasma generator 1104, while inner electrode 112 is electrically grounded. As shown in FIG. 17, capacitive controller 1112 is provided to adjust coupling between outer electrode 114 and showerhead electrode 105. As another example, FIG. 18 schematically shows process station 1800, wherein high frequency plasma generator 1102 and low frequency plasma generator 1104 are electrically connected with showerhead electrode 105 and inner electrode 112 while outer electrode 114 is electrically grounded. In the example shown in FIG, 18, capacitive controller 1112 is provided to adjust inner electrode 112 so that outer electrode 114 is coupled with inner electrode 112.

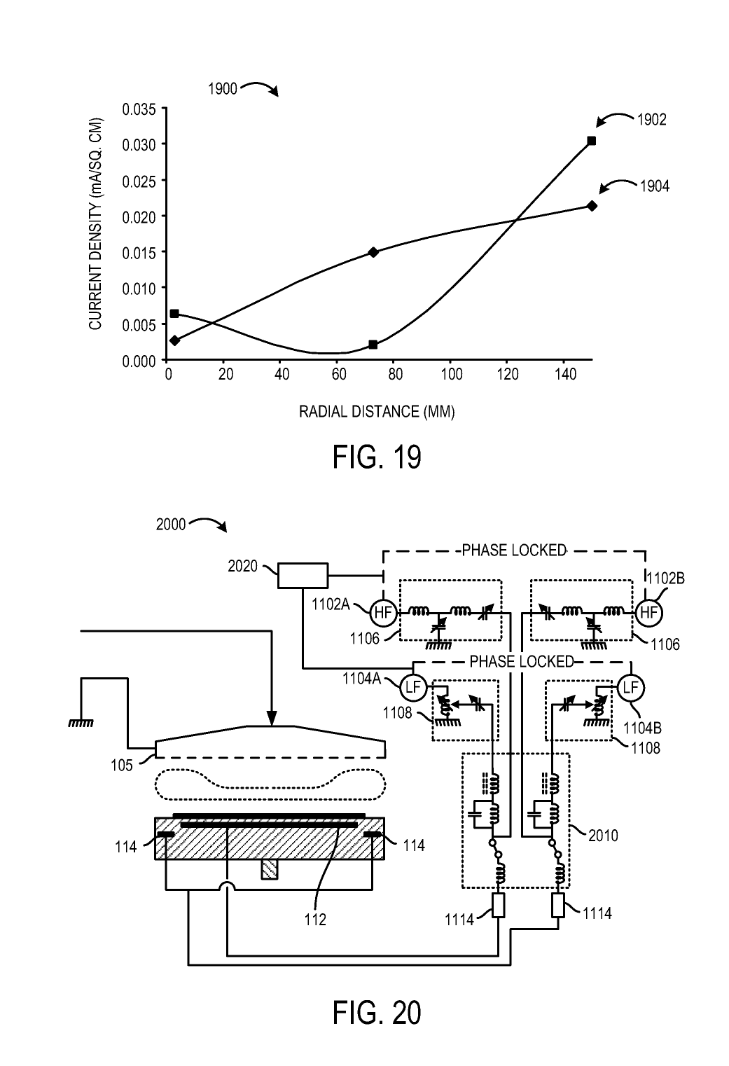

FIG. 19 shows a graph 1900 illustrating radial current density profiles for a variable-density plasma generated via the configuration of shown by process station 1700 (curve 1902) and a variable-density plasma generated via the configuration of shown by process station 1800 (curve 1904). While each configuration may be adjusted to provide a variable-density plasma having a greater plasma density at an outer region of the plasma than in an inner region of the plasma, it will be appreciated, from the data presented, in FIG. 19 that directly powering the outer electrode, as in the example shown in FIG. 17, may provide a comparatively higher current density at the edge of the radial profile relative to an indirectly-powered outer electrode such as that shown in FIG. 18.

While the example coupling configurations described above are directed at splitting both of a high-frequency and a low-frequency plasma power between two or more electrodes, it will be appreciated that, in some embodiments, only one of the high-frequency and low-frequency plasma power may be divided. For example, in some embodiments where two radio frequency sources are used concurrently to generate the plasma, only a high-frequency power may be divided between the outer electrode and the second electrode while a low-frequency power may be supplied to only one of the outer electrode and the second electrode. This may provide tuning capability for the plasma energy and/or density within a predefined region of the variable-density plasma. For example, under some plasma conditions, a low-frequency RF source may be used to control ion energy while a high-frequency RF source may be used to control plasma density. Thus, in one scenario, low-frequency plasma power may be supplied exclusively to the inner electrode, while high-frequency plasma energy may be supplied to both the inner electrode and the outer electrode. This may result in additional ion bombardment in an inner region of the plasma, while providing additional plasma density in an outer region of the plasma. It will be appreciated that the above-described example approach is non-limiting. For example, in another embodiment, low-frequency power may be divided between the outer electrode and the inner electrode while high-frequency plasma power is provided to the outer electrode.

While the example power supply configurations described above are directed at supplying plasma power to two electrodes from a single plasma generator, it will be appreciated that some embodiments may provide a plurality of plasma generators. As explained above, a plurality of plasma generators may provide substantially independent control of the various electrodes. For example, in some embodiments, a process station may comprise two or more plasma generators, each generator being electrically connected to a different electrode. FIG. 20 schematically shows a process station 2000 having two high-frequency plasma generators 1102 and two low-frequency plasma generators 1104. As shown in FIG. 20, the high-frequency plasma generators 1102 are phase-locked with one another, as are the low-frequency plasma generators 1104. Further, a synchronized matching network circuit 2020 is provided to provide a fast synchronization time (faster than 5 msec in one non-limiting example) and to damp power oscillations between the between the plasma sources. Additionally or alternatively, in some embodiments, synchronized matching network circuit 2020 may include a frequency tuning circuit configured to match a first pair of generators (e.g., high-frequency plasma generator 1102A and low-frequency plasma generator 1104A) to a fixed impedance of a second pair of generators (e.g., high-frequency plasma generator 1102B and low-frequency plasma generator 1104B).

While the hardware descriptions above relate to single process stations, it will be appreciated that, in some embodiments, two or more process stations may be included in a process tool. In some of such embodiments, control and/or supply of various process inputs (e.g., process gases, plasma power, heater power, etc.) may be distributed from shared sources to a plurality of process stations included in the process tool. For example, in some embodiments, a shared plasma generator may supply plasma power to two or more process stations. In another example, a shared gas distribution manifold may supply process gases to two or more process stations.

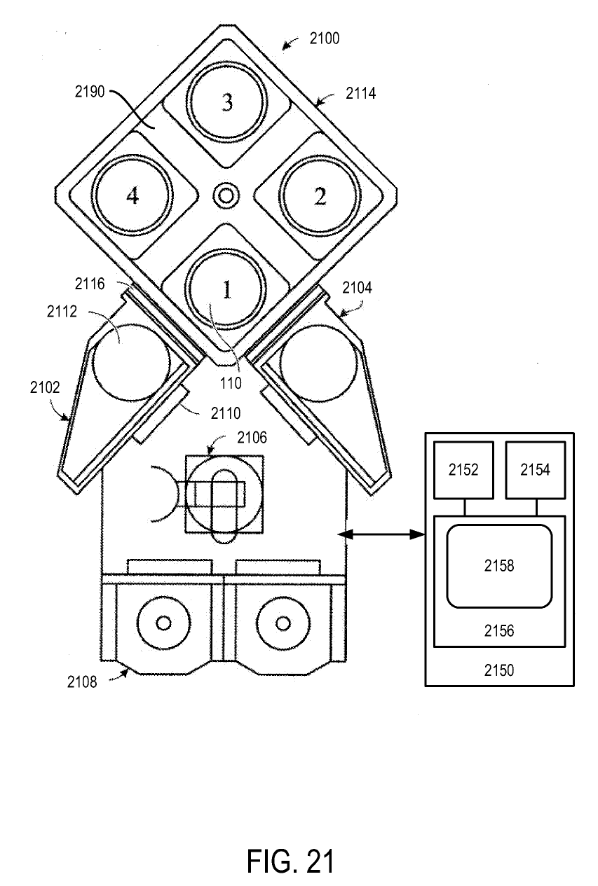

FIG. 21 shows a schematic view of an embodiment of a multi-station processing tool 2100 with an inbound load lock 2102 and an outbound load lock 2104. A robot 2106, at atmospheric pressure, is configured to move substrates from a cassette loaded through a pod 2108 into inbound load lock 2102 via an atmospheric port 2110. Inbound load lock 2102 is coupled to a vacuum source (not shown) so that, when atmospheric port 2110 is closed, inbound load lock 2102 may be pumped down. Inbound load lock 2102 also includes a chamber transport port 2116 interfaced with processing chamber 2114. Thus, when chamber transport port 2116 is opened, another robot (not shown) may move the substrate from inbound load lock 2102 to a pedestal of a first process station for processing.

In some embodiments, inbound load lock 2102 may be connected to a remote plasma source (not shown) configured to supply a plasma to load lock. This may provide remote plasma treatments to a substrate positioned in inbound load lock 2102. Additionally or alternatively, in some embodiments, inbound load lock 2102 may include a heater (not shown) configured to heat a substrate. This may remove moisture and gases adsorbed on a substrate positioned in inbound load lock 2102. While the embodiment depicted in FIG. 21 includes load locks, it will be appreciated that, in some embodiments, direct entry of a substrate into a process station may be provided.

The depicted processing chamber 2114 comprises four process stations, numbered from 1 to 4 in the embodiment shown in FIG. 21. In some embodiments, processing chamber 2114 may be configured to maintain a low pressure environment so that substrates may be transferred among the process stations without experiencing a vacuum break and/or air exposure. Each process station depicted in FIG. 21 includes a process station substrate holder (shown at 110 for station 1) and process gas delivery line inlets. In some embodiments, one or more process station substrate holders 110 may be heated.

In some embodiments, each process station may have different or multiple purposes. For example, a process station may be switchable between a PECVD or CVD mode, or between various etch modes, or between deposition and etch modes. Additionally or alternatively, in some embodiments, processing chamber 2114 may include one or more matched, pairs of deposition and etch process stations, so that a film may be deposited and etched in the same process chamber. In another example, a process station may be switchable between deposition processes for two or more film types, so that stacks of different film types may be deposited in the same process chamber.

While the depicted processing chamber 2114 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 21 also depicts an embodiment of a substrate handling system 2190 for transferring substrates within processing chamber 2114. In some embodiments, substrate handling system 2190 may be configured to transfer substrates between various process stations and/or between a process station and a load lock. It will be appreciated that any suitable substrate handling system may be employed. Non-limiting examples include substrate carousels and substrate handling robots.

FIG. 21 also depicts an embodiment of a system controller 2150 employed to control process conditions and hardware states of processing tool 2100. For example, in some embodiments, system controller 2150 may include instructions for controlling embodiments of the hardware described, above (e.g., plasma generators including hollow-cathode magnetrons and planar magnetrons, plasma controllers and power distribution circuits, substrate holder heater controllers, mass flow controllers, pressure control devices, etc.) to perform embodiments of the method described above.

System controller 2150 may include one or more memory devices 2156, one or more mass storage devices 2154, and one or more processors 2152. Processor 2152 may include a CPU or computer, analog and/or digital input/output connections, stepper motor controller boards, etc.

In some embodiments, system controller 2150 may control ail of the activities of processing tool 2100. In some embodiments, system controller 2150 executes machine-readable system control software 2158 stored in mass storage device 2154 or other suitable machine-readable media, loaded into memory device 2156, and executed on processor 2152. System control software 2158 may include instructions for controlling the timing, mixture of gases, chamber and/or station pressure, chamber and/or station temperature, substrate temperature, target power levels, RF power levels, substrate pedestal, chuck and/or susceptor position, and other parameters of a particular process performed by processing tool 2100. System control software 2158 may be configured in any suitable way. For example, various process tool component subroutines or control objects may be written to control operation of the process tool components for performing various process tool processes. System control software 2158 may be coded in any suitable computer readable programming language.

In some embodiments, system control software 2158 may include input/output control (IOC) sequencing instructions for controlling the various parameters described above. For example, each phase of a variable-density plasma process may include one or more instructions for execution by system controller 2150. The instructions for setting process conditions for a variable-density plasma process phase may be included in a corresponding a variable-density plasma recipe phase. In some embodiments, the variable-density plasma PECVD recipe phases may be sequentially arranged, so that all instructions for a variable-density plasma process phase are executed concurrently with that process phase.

Other computer software and/or programs stored on mass storage device 2154 and/or memory device 2156 associated with system controller 2150 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto process station substrate holder 110 and to control the spacing between the substrate and other parts of processing tool 2100.

A process gas control program may include code for controlling gas composition and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations.

In some embodiments, there may be a user interface associated with system controller 2150. The user interface may include a display screen, graphical software displays of the apparatus and/or process conditions, and user input devices such as pointing devices, keyboards, touch screens, microphones, etc.

In some embodiments, parameters adjusted by system controller 2150 may relate to process conditions. Non-limiting examples include process gas composition and flow rates, temperature, pressure, plasma conditions (such as RF bias power levels), pressure, temperature, etc. These parameters may be provided, to the user in the form of a recipe, which may be entered, utilizing the user interface.

Signals for monitoring the process may be provided by analog and/or digital input connections of system controller 2150 from various process tool sensors. The signals for controlling the process may be output on the analog and digital output connections of processing tool 2100. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 2150 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The various hardware and method embodiments described above may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility.

Lithographic patterning of a film typically comprises some or all of the following steps, each step enabled with a number of possible tools: (1) application of photoresist on a workpiece, i.e. substrate, using a spin-on or spray-on tool; (2) curing of photoresist using a hot plate or furnace or other suitable curing tool; (3) exposing the photoresist to visible or UV or x-ray light with a tool such as a wafer stepper; (4) developing the resist so as to selectively remove resist and thereby pattern it using a tool such as a wet bench or a spray developer; (5) transferring the resist pattern into an underlying film or workpiece by using a dry or plasma-assisted etching tool; and (6) removing the resist using a tool such as an RF or microwave plasma resist stripper. In some embodiments, an ashable hard mask layer (such as an amorphous carbon layer) and another suitable hard mask (such as an antireflective layer) may be deposited prior to applying the photoresist.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated may be performed in the sequence illustrated, in other sequences, in parallel, or in some cases omitted. Likewise, the order of the above-described processes may be changed.

The subject matter of the present disclosure includes all novel and nonobvious combinations and subcombinations of the various processes, systems and configurations, and other features, functions, acts, and/or properties disclosed herein, as well as any and all equivalents thereof.

1. A semiconductor substrate process station, comprising:
a showerhead including a showerhead electrode;
a substrate holder including a mesa comprising a mesa surface configured to support a substrate, the substrate holder disposed beneath the showerhead, and the substrate holder including an inner electrode disposed in an inner region of the substrate holder and an outer electrode being disposed in an outer region of the substrate holder;
a plasma generator configured to generate a plasma in a plasma region disposed between the showerhead and the substrate holder; and
a controller comprising instructions stored in memory and executable by a processor to control the plasma generator, the inner electrode, the outer electrode, and the showerhead electrode to effect a greater plasma density in an outer portion of the plasma region than in an inner portion of the plasma region by coupling the outer electrode with a second electrode selected from one of the inner electrode and the showerhead electrode.

2. The process station of claim 1, wherein a geometric center of the inner electrode is concentric with a geometric center of the mesa surface and with a geometric center of the outer electrode.

3. The process station of claim 1, wherein high-frequency power supplied by the plasma generator is divided between the outer electrode and the second electrode, and wherein low frequency power supplied by the plasma generator is supplied to only one of the outer electrode and the second electrode.

4. The process station of claim 1, wherein the controller is configured to vary an impedance of a power branch electrically connected to the outer electrode to affect a power balance between the outer electrode and the second electrode.

5. The process station of claim 1, wherein the plasma generator is a first plasma generator, and further comprising a second plasma generator in electrical communication with the outer electrode and the second electrode, the controller configured to control the outer electrode with the first plasma generator and the second electrode with the second plasma generator, the first plasma generator and the second plasma generator being phase-locked to each other.

6. The process station of claim 5, further comprising a synchronized matching network circuit configured to match a respective impedance of the first plasma generator and the second plasma generator to damp power oscillations between the outer electrode and the second electrode.

7. The process station of claim 1, further comprising a dual-branch distribution circuit configured to divide power to a first power branch electrically connected with the outer electrode and a second, power branch electrically connected with the second electrode.

8. A substrate holder for a semiconductor substrate process station, comprising:
a mesa comprising a dielectric material, the mesa having a top surface configured to support a substrate;
an inner electrode disposed in a first plane below the top surface; and
an outer electrode disposed in a second plane below the top surface;
wherein a first layer of dielectric material separates the inner electrode from the outer electrode, and wherein a second layer of dielectric material separates both the inner electrode and the outer electrode from the top surface.

9. The substrate holder of claim 8, wherein a geometric center of the inner electrode is concentric with a geometric center of the mesa and with a geometric center of the outer electrode.

10. The substrate holder of claim 9, wherein the outer electrode is substantially ring-shaped, wherein the inner electrode is substantially disc-shaped, and wherein an inner diameter of the outer electrode is greater than a maximum diameter of the inner electrode.

11. The substrate holder of claim 9, wherein the inner electrode has a maximum dimension that is smaller than a maximum dimension of the substrate.

12. The substrate holder of claim 8, wherein the second plane is disposed below the first plane, and wherein the outer electrode is electrically connected to an outer electrode power bus by a conductive arm, the conductive arm being separated from the inner electrode by a dielectric material.

13. The substrate holder of claim 8, wherein the dielectric material includes aluminum nitride, and wherein the outer electrode and the inner electrode each include aluminum.

14. The substrate holder of claim 8, the outer electrode being one of a plurality of outer electrodes, one or more of the plurality of outer electrodes being electrically isolated from the other of the plurality of outer electrodes.

15. The substrate holder of claim 8, wherein one or more of the outer electrode and the inner electrode comprises one or more of a metal mesh and a lithographically patterned metal film, and the dielectric material comprises a compacted ceramic.

16. The substrate holder of claim 8, further comprising a column joined to an underside of the mesa, the column including a flange configured to sealably retain the substrate holder in a vacuum environment so that an interior portion of the column may maintain a pressure higher than that of the vacuum environment.

17. A method of processing a semiconductor substrate by generating a variable-density plasma in a semiconductor substrate process station, the semiconductor substrate process station including a showerhead for distributing plasma gas to the variable-density plasma, a plasma generator for generating the variable-density plasma, and a substrate holder for supporting a substrate with respect to the showerhead so that the substrate is exposed to the variable-density plasma, the method comprising:
supplying a plasma gas to the semiconductor substrate process station;
generating the variable-density plasma by:
coupling the outer electrode with a second electrode selected from one of the inner electrode and the showerhead electrode, and
setting an impedance of a circuit supplying power from the plasma generator to one of the outer electrode and the second electrode so that the plasma density of an outer portion of the plasma region is greater than the plasma density of a inner portion of the plasma region; and
processing the substrate with the variable-density plasma.

18. The method of claim 17, further comprising extinguishing the variable-density plasma after processing the substrate by adjusting the power supplied by the plasma generator so that the variable-density plasma is extinguished in the inner portion of the plasma region before being extinguished in the outer portion of the plasma region,

19. The method of claim 17, wherein processing the substrate with the variable-density plasma comprises setting the capacitance of the circuit to set the shape of the variable-density plasma to effect, during processing of the substrate, an offset to a within-substrate non-uniformity profile of the semiconductor substrate, the within-substrate non-uniformity profile being exhibited by the semiconductor substrate prior to processing at the semiconductor substrate process tool.

20. The method of claim 17, further comprising:
applying a photoresist to the substrate;
exposing the photoresist to light;
patterning the resist with a pattern and transferring the pattern from the resist to the substrate; and
selectively removing the photoresist from the substrate.
